(19) United States
(12) Patent Application Publication
(10) Pub. No.: US 2011/0193548 A1
(43) Pub. Date: Aug. 11, 2011

(54) SEPARATION-TYPE AVOMETER

(75) Inventor: Hsin-Chen Ko, Taipei (TW)

(73) Assignee: APPA TECHNOLOGY CORP., Taipei (TW)

(21) Appl. No.: 12/701,006

(22) Filed: Feb. 5, 2010

(51) Int. Cl. G01R 1/00

(52) U.S. Cl. 324/114

(57) ABSTRACT

A separation-type avometer includes a manipulation device and a measurement main body. The manipulation device includes a selection module, a first wireless module, and a window module. The measurement main body includes a measurement module, a second wireless module, and an automatic determining and switching module. The first wireless module transmits a measurement mode selected through the selection module to the second wireless module of the measurement main body. The automatic determining and switching module switches the measurement mode of the measurement module according to the selected measurement mode. After the measurement is completed, the second wireless module transmits signal data measured by the measurement main body to the first wireless module of the manipulation device, so as to use the window module to display the signal data measured by the measurement main body.

### BACKGROUND OF THE INVENTION

1. Field of Invention

The present invention relates to a separation-type avometer, and more particularly to a separation-type avometer including a measurement main body and a manipulation device, which can rapidly complete electrical measurement and perform multi-point measurement at the same time by bi-directional wireless reading and controlling between the measurement main body and the manipulation device.

2. Related Art

Conventional avometers can be generally divided into two types, that is, electronic liquid crystal display (LCD) avometers and mechanical avometers. Except for the difference in display mode, common avometers are all provided with operation knobs for multi-stage function switching and function indications marked around the operation knob. As such, according to the items to be detected, an operator can manually move and switch the knobs to select a related electrical property and a position within the scope of value to be measured, so as to measure alternating current (AC) voltage and current, direct current (DC) voltage and current, resistance, or connection of electrodes.

For the aforementioned avometers, in use, a test bar or a hook-type current sensing bar is connected to a current carrier for measurement, and a measured electrical value of the current carrier is read by an electronic LCD or a mechanical metering pin. However, since the length of wire leads for connecting the test bar and the avometer body is limited, when an electrical measurement point on the current carrier is at a position that cannot be reached by the operator, the operator cannot easily perform measurement by using the test bar or the hook-type current sensing bar. Furthermore, when the aforementioned avometers are used to perform measurement at multiple measurement points in a complicated power supply circuit, since the aforementioned avometers cannot record the results of different measurement points at the same time, the measurement cannot be performed successfully.

In view of the above, in order to eliminate the aforementioned defects, and enable an avometer to perform electrical measurement under difficult working conditions by a separation-type display device which has a storage module for storing signal data of measurement results so as to record measurement results of multiple measurement points, the present invention is made by the inventor through years of experience and continuous research, development and improvement.

### SUMMARY OF THE INVENTION

Accordingly, the present invention is mainly directed to a separation-type avometer, in which a first wireless module of a manipulation device transmits a selected measurement mode signal to a second wireless module of a measurement main body through wireless transmission, such that the measurement main body automatically switches to a corresponding measurement mode, so as to apply the selected measurement mode.

The present invention is also directed to a separation-type avometer, in which a measurement main body outputs a signal measured by a measurement module to a manipulation device through wireless transmission, and a window module of the manipulation device is used to display the signal from the measurement main body, so as to improve the convenience in electrical measurement.

In order to achieve the above objectives, the present invention provides a separation-type avometer, which includes a manipulation device and a measurement main body. The manipulation device includes a selection module, a first wireless module, and a window module. The selection module is provided for an operator to select at least one measurement mode. The first wireless module includes a measurement mode signal output unit connected to the selection module and a measurement signal receiving unit. The measurement mode signal output unit outputs a measurement mode selected by the operator through wireless transmission. The measurement signal receiving unit is used to receive signal data measured by the measurement main body. The window module is connected to the measurement signal receiving unit, and is used to display the signal data. The measurement main body includes a measurement module, a second wireless module, and an automatic determining and switching module. The measurement module is provided with a testing element for contacting an object to be measured. The second wireless module includes a measurement mode signal receiving unit and a measurement signal output unit connected to the measurement module. The measurement mode signal receiving unit is used to receive a measurement mode signal transmitted by the measurement mode signal output unit. After the measurement, the measurement signal output unit is used to output signal data measured by the measurement module to the measurement signal receiving unit through wireless transmission. The automatic determining and switching module is connected between the measurement module and the measurement mode signal receiving unit, such that after the measurement mode signal receiving unit receives the measurement mode signal, the automatic determining and switching module automatically switches to a corresponding measurement mode, so as to enable the measurement module to apply the measurement mode set by the operator.

In the implementation, the measurement mode includes a resistance measurement mode, a diode measurement mode, a direct current (DC) voltage measurement mode, an alternating current (AC) voltage measurement mode, and an AC/DC current measurement mode.

In the implementation, the testing element is a set of test probes.

In the implementation, the manipulation device further includes a storage module, connected to the measurement signal receiving unit, for storing the signal data measured by the measurement main body that is received by the measurement signal receiving unit. Furthermore, the storage module includes a wireless transmission unit, for transmitting the signal data in the storage module to a remote device.

In the implementation, the manipulation device further includes a fixing element, for example, an annular wristlet, for fixing the manipulation device to an object.

In the implementation, the window module includes a display unit and a touch control unit. The display unit is used to display the signal data measured by the measurement main body. The touch control unit is connected to the selection module, so as to enable the operator to select a measurement mode by touching the touch control unit.

In order to make the present invention more comprehensible, features and effects of the present invention are described in detail below through preferred embodiments with reference to the drawings and drawing numbers.

### BRIEF DESCRIPTION OF THE DRAWINGS

The present invention will become more fully understood from the detailed description given herein below for illustration only, and thus are not limitative of the present invention, and wherein:

FIG. 1 is a schematic outside view of an embodiment of the separation-type avometer of the present invention;

FIG. 2 is a schematic block diagram of a basic architecture of the embodiment in FIG. 1;

FIG. 3 is a flow chart illustrating automatic determination and mode switching in the embodiment in FIG. 1; and

FIG. 4 is a schematic view of an application of the embodiment in FIG. 1 when combined with a fixing band.

### DETAILED DESCRIPTION OF THE INVENTION

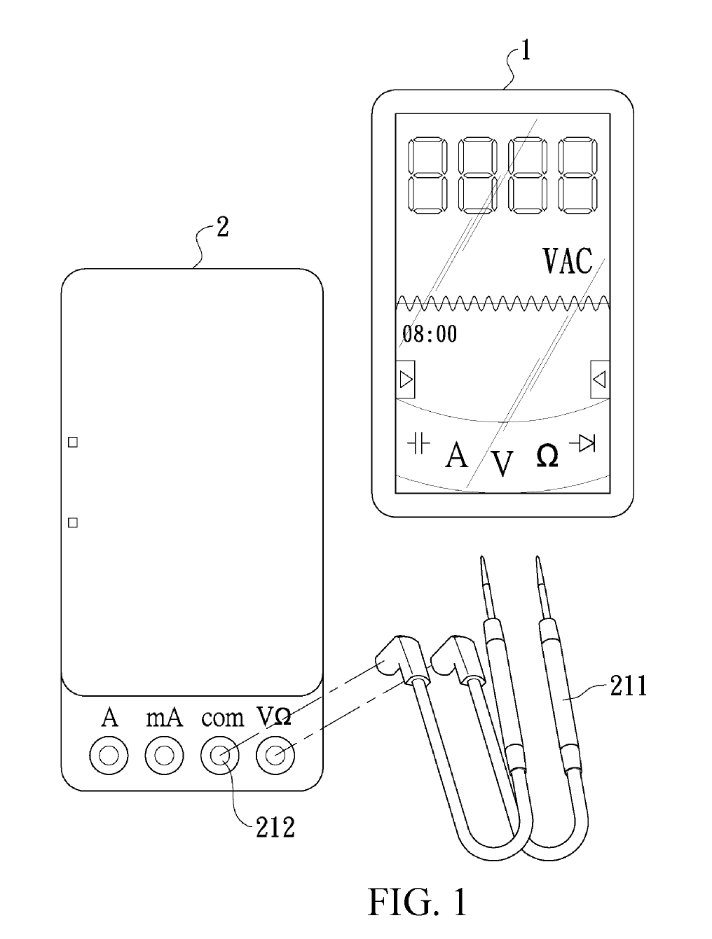

FIG. 1 shows an embodiment of the separation-type avometer of the present invention. Referring to FIG. 1, the separation-type avometer includes a manipulation device 1 and a measurement main body 2 that can be integrated with the manipulation device 1 into one piece.

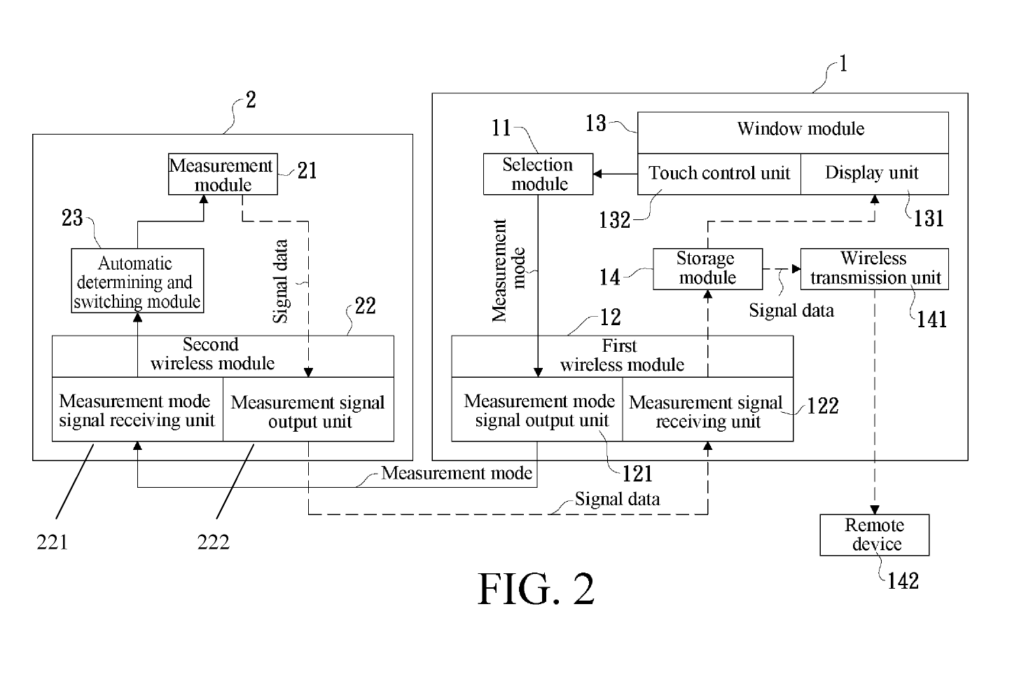

As shown in FIG. 2, the manipulation device 1 includes a selection module 11, a first wireless module 12, and a window module 13. The selection module 11 is provided for an operator to select at least one measurement mode, for example, a resistance measurement mode, a diode measurement mode, a direct current (DC) voltage measurement mode, an alternating current (AC) voltage measurement mode, and an AC/DC current measurement mode. The first wireless module 12 includes a measurement mode signal output unit 121 and a measurement signal receiving unit 122. The measurement mode signal output unit 121 is connected to the selection module 11, and outputs a measurement mode selected by the operator through wireless transmission. The measurement signal receiving unit 122 is used to receive signal data measured by the measurement main body 2. The window module 13 includes a display unit 131 and a touch control unit 132. The display unit 131 is connected to the measurement signal receiving unit 122, and is used to display the signal data measured by the measurement main body 2. The touch control unit 132 is connected to the selection module 11, so as to enable the operator to select a measurement mode by touching the touch control unit 132.

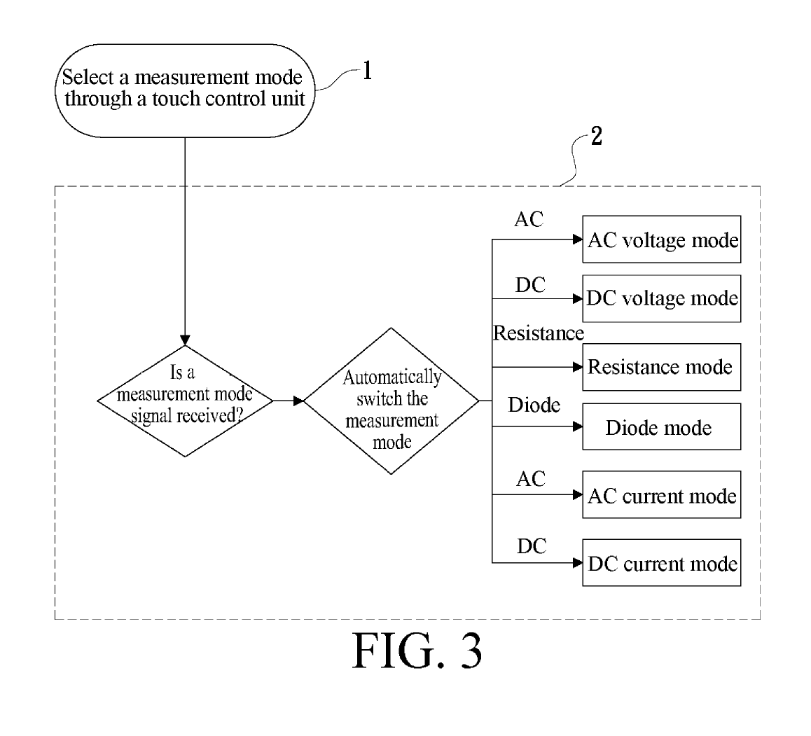

The measurement main body 2 includes a measurement module 21, a second wireless module 22, and an automatic determining and switching module 23. The measurement module 21 is provided with a testing element 211 for contacting an object to be measured and a plurality of jacks 212 for inserting the testing element 211 therein. The testing element 211 is a set of test probes. The second wireless module 22 includes a measurement mode signal receiving unit 221 and a measurement signal output unit 222. The measurement mode signal receiving unit 221 is used to receive a measurement mode signal transmitted by the measurement mode signal output unit 121. The measurement signal output unit 222 is connected to the measurement module 21, and transmits signal data generated by the measurement module after measurement to the measurement signal receiving unit 122 through wireless transmission. The automatic determining and switching module 23 is connected between the measurement module 21 and the measurement mode signal receiving unit 221, such that after the measurement mode signal receiving unit 221 receives the measurement mode signal from the manipulation device 1, the automatic determining and switching module 12 automatically switches to a corresponding measurement mode, so as to enable the measurement module 21 to apply the measurement mode set by the operator (as shown in FIG. 3).

In the implementation, one end of the testing element 211 is inserted into the jacks 212, the measurement mode of the measurement main body 2 is selected through the touch control unit 132 of the manipulation device 1, and then, the other end of the testing element 211 is connected to the object to be measured (not shown), so as to perform electrical measurement. Next, after the measurement is completed, the measurement main body 2 uses the second wireless module 22 to transmit the signal data measured by the measurement module to the measurement signal receiving unit 122 of the manipulation device 1 through wireless transmission, and then, the signal data is displayed on the display unit 131 of the manipulation device 1.

In the implementation, the manipulation device 1 further includes a storage module 14 having a wireless transmission unit 141. The storage module 14 is connected to the measurement signal receiving unit 122, and is used for storing the signal data received by the measurement signal receiving unit 122 from the measurement main body 2. The wireless transmission unit 141 is used for transmitting the signal data to a remote device 142 for display or storage.

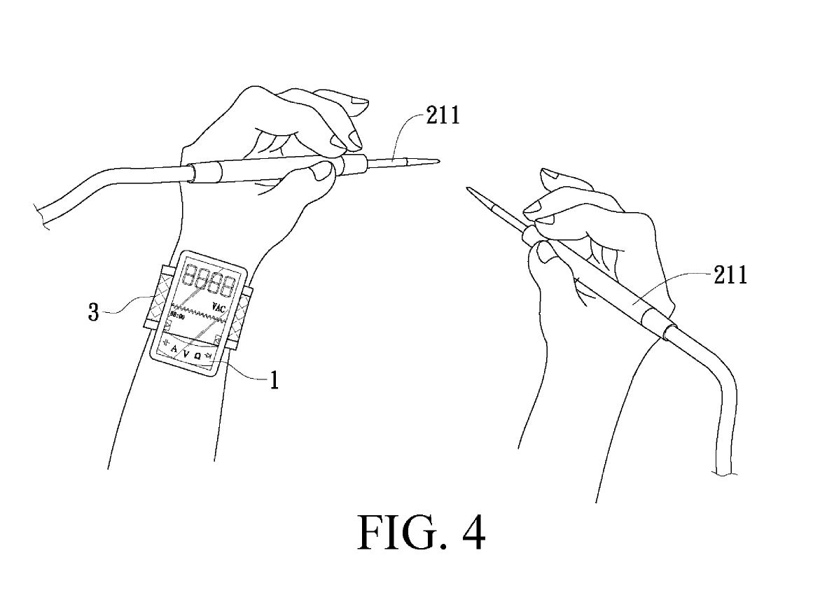

In the implementation, the manipulation device 1 is combined to a fixing band 3 such as an annular wristlet (as shown in FIG. 4), so as to fix the manipulation device 1 to the arm or waist of the operator. Alternatively, the manipulation device is fixed to an object by a fixing element which is a magnetic body. As such, after the electrical measurement is completed, the operator can conveniently view the information about electrical values measured by the measurement main body 2 directly from the display unit 131 of the manipulation device 1, thereby improving the convenience and efficiency of the measurement.

Therefore, the present invention has the following advantages.

1. The present invention improves the measurement mode of conventional avometers by separating the measurement main body from the manipulation device, and using the manipulation device to select a measurement mode and display results of signal data through wireless transmission. As such, in an environment that is difficult for electrical measurement, an operator can rapidly perform various measurement operations or switch the measurement mode simply by operating the manipulation device, such that the actions and time required for operating the avometer are reduced while protecting the operator, thereby improving the use convenience and practicability of the separation-type avometer.

2. The present invention can perform multi-point measurement during electrical measurement of a complicated circuit by bi-directional reading and controlling, and rapidly store the signal data of different measurement points, thereby greatly reducing the measurement time and manpower cost.

In view of the above, according to the aforementioned disclosure, the present invention surely can achieve the expected objectives to provide a separation-type avometer that can transmit the measurement result of the measurement main body to the display unit through wireless transmission, and rapidly perform multi-point measurement by bi-directional reading and controlling. Therefore, the present invention has industrial applicability and thus, the application for a patent is filed according to the law.

What is claimed is:

1. A separation-type avometer, comprising a manipulation device and a measurement main body, wherein
the manipulation device comprises:
a selection module, comprising at least one measurement mode for an operator to select;
a first wireless module, comprising a measurement mode signal output unit and a measurement signal receiving unit, wherein the measurement mode signal output unit is connected to the selection module, and outputs a measurement mode selected by the operator through wireless transmission, and the measurement signal receiving unit is used to receive signal data measured by the measurement main body; and
a window module, connected to the measurement signal receiving unit, for displaying the signal data measured by the measurement main body; and
the measurement main body comprises:
a measurement module, provided with a testing element for contacting an object to be measured;
a second wireless module, comprising a measurement mode signal receiving unit and a measurement signal output unit, wherein the measurement mode signal receiving unit is used to receive a measurement mode signal transmitted by the measurement mode signal output unit, and the measurement signal output unit is connected to the measurement module, and outputs signal data measured by the measurement module to the measurement signal receiving unit through wireless transmission; and
an automatic determining and switching module, connected between the measurement module and the measurement mode signal receiving unit, such that after the measurement mode signal receiving unit receives the measurement mode signal, the automatic determining and switching module automatically switches to a corresponding measurement mode, so as to enable the measurement module to apply the measurement mode set by the operator.

2. The separation-type avometer according to claim 1, wherein the measurement mode comprises a resistance measurement mode, a diode measurement mode, a direct current (DC) voltage measurement mode, an alternating current (AC) voltage measurement mode, and an AC/DC current measurement mode.

3. The separation-type avometer according to claim 1, wherein the testing element is a set of test probes.

4. The separation-type avometer according to claim 1, wherein the manipulation device further comprises a storage module, connected to the measurement signal receiving unit, for storing the signal data measured by the measurement main body that is received by the measurement signal receiving unit.

5. The separation-type avometer according to claim 4, wherein the storage module comprises a wireless transmission unit, for transmitting the signal data in the storage module to a remote device.

6. The separation-type avometer according to claim 1, wherein the manipulation device further comprises a fixing element for fixing the manipulation device to an object.

7. The separation-type avometer according to claim 6, wherein the fixing element is an annular wristlet.

8. The separation-type avometer according to claim 6, wherein the fixing element is a magnetic body.

9. The separation-type avometer according to claim 1, wherein the window module comprises a display unit and a touch control unit, the display unit is used to display the signal data measured by the measurement main body, and the touch control unit is connected to the selection module, so as to enable the operator to select a measurement mode by touching the touch control unit.
